(19) United States
(12) Patent Application Publication
(10) Pub. No.: US 2026/0352156 A1
(43) Pub. Date: Nov. 5, 2026

(54) CURRENT SENSE AMPLIFIER WITH PULSE GENERATION CIRCUIT

(71) Applicant: SAMSUNG ELECTRONICS CO., LTD., Suwon-si (KR)

(72) Inventors: Saumen MONDAL, Bangalore (IN); Deepa DEVENDRAN, Bangalore (IN)

(73) Assignee: SAMSUNG ELECTRONICS CO., LTD., Suwon-si (KR)

(21) Appl. No.: 19/371,730

(22) Filed: Oct. 28, 2025

(30) Foreign Application Priority Data
Apr. 30, 2025 (IN) 202541041872
Jul. 18, 2025 (IN) 202541041872

(51) Int. Cl. H03F 1/02; H02M 3/158; H03F 3/21

(52) U.S. Cl. CPC H03F 1/0205; H03F 3/21; H02M 3/1582; H03F 2200/462

(57) ABSTRACT

A current sense amplifier includes a current sense amplifier core structure including a pair of power field effect transistors (FETs), a start-up circuit including a start-up switch coupled with a FET, and a pulse generation circuit configured to switch on the start-up circuit for a predefined time duration. The FET is grounded and coupled with the pair of power FETs via the start-up switch. The start-up circuit is configured to change a zero-current state of the current sense amplifier core structure to an active state.

### CROSS-REFERENCE TO RELATED APPLICATIONS

This application claims priority under 35 U.S.C. § 119 to Indian Provisional Patent Application No. 202541041872, filed on Apr. 30, 2025, and to Indian Patent Application No. 202541041872, filed on Jul. 18, 2025, filed in the Indian Patent Office, the disclosures of which are incorporated by reference herein in their entireties.

### BACKGROUND

### 1. Field

The present disclosure relates generally to voltage regulators, and more particularly, to a current sense amplifier with a pulse generation circuit.

### 2. Description of Related Art

Buck-boost converters may be used in applications where a regulated output voltage may be needed irrespective of input voltage level fluctuations, such as, but not limited to, laptops, tablets, mobile devices, battery chargers, or the like. These applications may demand relatively precise regulation of output voltage and/or current to potentially provide stable performance, particularly in dynamic conditions.

A buck-boost converter may refer to a type of direct current (DC)-DC converter that may step down (buck) and/or step up (boost) an input voltage while providing an output voltage that may have a same polarity as the input voltage. The buck-boost converter may employ a combination of inductors, capacitors, and switches (e.g., metal-oxide semiconductor field-effect transistor (MOSFETs)) to regulate the output voltage, which may provide for the non-inverting buck-boost converter to potentially maintain efficiency across a wide range of input-output voltages. A buck-boost converter may be useful in applications where the supply voltage may fluctuate above and/or below a desired output level, by providing a stable voltage supply for devices that may include, but not be limited to, battery chargers, power supplies, renewable energy systems, or the like. Such a topology may be favored for its relative simplicity, relatively low component count, and ability to potentially provide versatile voltage regulation.

For example, a current flowing through a power field effect transistor (FET) switch may represent a critical parameter for a control loop of the buck-boost converter. That is, a fraction of a total current may be sensed (e.g., 1/Nₛₑₙₛₑ×total current), may be processed by a current sense amplifier, and may be fed back to the control loop to regulate the operation of the buck-boost converter. As another example, a speed of the feedback loop may also represent a critical parameter, in particular, in applications with changing load conditions. Under dynamic or changing load conditions, the buck-boost converter may need to respond relatively quickly to provide a relatively stable operation and provide an output voltage within desired tolerances. For example, a minimum on-time for the switch may be as short as 150 nanoseconds (ns) in order for the current sense amplifier to track the current through the power switch effectively. Thus, switching speed may be a critical constraint for fast-switching converters. When the buck-boost converter operates in peak current mode control, the current sense amplifier may need to react to changes in current within this minimum on-time, which may be challenging at such relatively high speeds (e.g., 150 ns). Thus, the current sense amplifier may need to capture the current waveform and relay the captured current waveform to the control loop in real time, ensuring that the feedback loop may adjust the duty cycle of the switching FETs and regulate the output voltage.

Thus, there exists a need for further improvements in current sense amplifiers, as the need for a stable output voltage within desired tolerances may be constrained by relatively high switching speeds. Improvements are presented herein. These improvements may also be applicable to other voltage regulation technologies.

### SUMMARY

This summary is provided to introduce a selection of concepts, in a simplified format, that are further described in the detailed description section below. This summary is neither intended to identify essential example embodiments nor is it intended for determining (or limiting) the scope of the present disclosure.

According to an aspect of the present disclosure, a current sense amplifier includes a current sense amplifier core structure including a pair of power field effect transistors (FETs), a start-up circuit including a start-up switch coupled with a FET, and a pulse generation circuit configured to switch on the start-up circuit for a predefined time duration. The FET is grounded and coupled with the pair of power FETs via the start-up switch. The start-up circuit is configured to change a zero-current state of the current sense amplifier core structure to an active state.

According to an aspect of the present disclosure, a method for reducing a response time of a current sense amplifier includes receiving, by a pulse generation circuit, a first input signal, and reducing the response time of the current sense amplifier by changing, using a start-up circuit, a zero-current state of the current sense amplifier to an active state based on the receiving of the first input signal.

Additional aspects may be set forth in part in the description which follows and, in part, may be apparent from the description, and/or may be learned by practice of the presented embodiments.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1A illustrates a circuit diagram of a converter, according to comparative example;

FIG. 1B illustrates a circuit diagram of a current sense amplifier performing dynamic switching, according to a comparative example;

FIG. 2 illustrates a circuit diagram of a current sense amplifier, according to an embodiment of the present disclosure; and

FIG. 3 illustrates a flowchart depicting a method for reducing response time of the current sense amplifier, according to an embodiment of the present disclosure.

### DETAILED DESCRIPTION

Hereinafter, reference is made to various example embodiments illustrated in the drawings and specific language may be used to describe the same. It is to be understood that no limitation of the scope of the present disclosure is thereby intended, such that embodiments of the present disclosure may not have to be configured as limited to the various example embodiments described below and may be embodied in various forms. The following various example embodiments are not provided to fully complete the present disclosure, but rather to fully convey the scope of the present disclosure to those of ordinary skill in the art.

It is to be understood by those skilled in the art that the foregoing general description and the following detailed description represent some example embodiments of the disclosure and are not intended to be restrictive thereof.

Further, skilled artisans may appreciate that elements in the drawings may be illustrated for simplicity and may not have necessarily been drawn to scale. For example, the flowcharts illustrate some example embodiments in terms of operations involved to help improve understanding of the present disclosure. Furthermore, regarding construction or assembly of some example embodiments, one or more components of some example embodiments may have been represented in the drawings by conventional symbols, and the drawings may show only those specific details that are pertinent (or beneficial) to understand some example embodiments of the present disclosure. Additionally, details that may be readily apparent to those of ordinary skill in the art may have been omitted from the drawings for ease of description.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

Reference throughout the present disclosure to “an aspect”, “another aspect” or similar language may indicate that a particular feature, structure, or characteristic described in connection with the example embodiments is included in at least one example embodiment. Thus, appearances of the phrase “in an example embodiment”, “in some example embodiments”, “in another example embodiment”, and similar language throughout the present disclosure may, but do not necessarily, all refer to the same example embodiment.

The terms “comprise”, “comprising”, or any other variations thereof, may be intended to cover a non-exclusive inclusion, such that a process or method that comprises a list of operations may not include only those operations but may include other operations not expressly listed or inherent to such process or method. Similarly, one or more devices or sub-systems or elements or structures or components preceded by “comprises . . . a” does not, without more constraints, preclude the existence of other devices or other sub-systems or other elements or other structures or other components or additional devices or additional sub-systems or additional elements or additional structures or additional components.

Some example embodiments herein and the various features and advantageous details thereof may be explained more fully with reference to the non-limiting example embodiments that are illustrated in the accompanying drawings and detailed in the following description. Descriptions of well-known components and processing techniques may be omitted so as to not unnecessarily obscure the example embodiments herein. The various example embodiments described herein are not necessarily mutually exclusive, as some example embodiments may be combined with one or more other example embodiments to form new example embodiments. The term “or”, as used herein, may refer to a non-exclusive or unless otherwise indicated. The examples used herein are intended merely to facilitate an understanding of ways in which the example embodiments herein may be practiced and to further enable those skilled in the art to practice the example embodiments herein. Accordingly, the examples should not be construed as limiting the scope of the example embodiments herein.

As is traditional in the field, example embodiments may be described and illustrated in terms of blocks that may carry out a described function or functions. These blocks, which may be referred to herein as units or modules or the like, may be physically implemented by analog or digital circuits such as, but not limited to, logic gates, integrated circuits, microprocessors, micro-controllers, memory circuits, passive electronic components, active electronic components, optical components, hardwired circuits, or the like, and may optionally be driven by firmware and software. The circuits may, for example, be embodied in one or more semiconductor chips, or on substrate supports such as, but not limited to, printed circuit boards (PCBs) or the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of example embodiments may be physically separated into two or more interacting and discrete blocks without departing from the scope of the present disclosure. Likewise, the blocks of the example embodiments may be physically combined into more complex blocks without departing from the scope of the present disclosure.

The accompanying drawings may be used to help easily understand various technical features and it should be understood that the example embodiments presented herein are not limited by the accompanying drawings. As such, the present disclosure should be construed to extend to any alterations, equivalents, and substitutes in addition to those which are particularly set out in the accompanying drawings. Although the terms first, second, or the like may be used herein to describe various elements, these elements should not be limited by these terms. These terms are generally only used to distinguish one element from another.

One or more example embodiments of the present disclosure enable a current sense amplifier to provide real-time current measurements for adjusting the duty cycle of the high-side switch.

Further, one or more example embodiments of the present disclosure enable the current sense amplifier to respond at a relatively high speed and track the current from the high-side switch.

Hereinafter, various embodiments of the present disclosure are described with reference to the accompanying drawings.

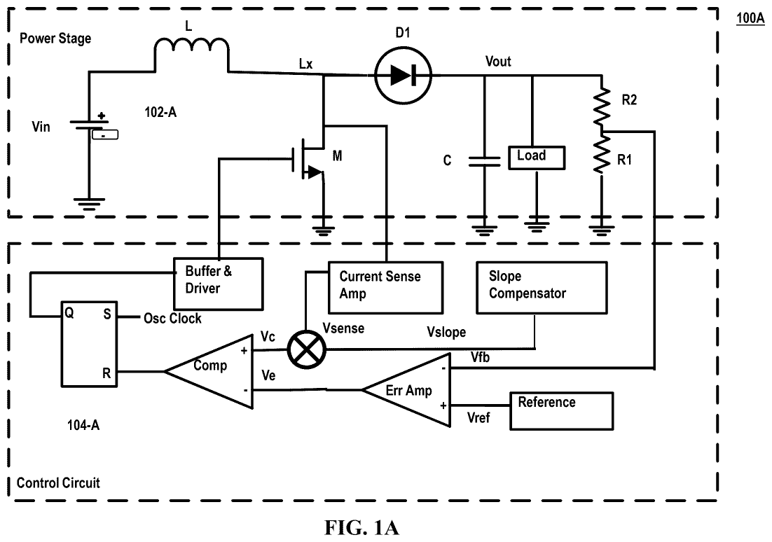

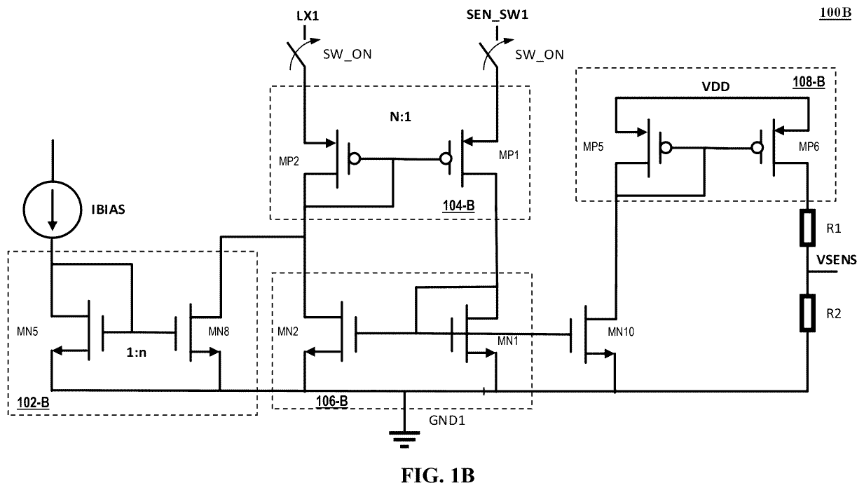

FIG. 1A illustrates a circuit diagram of a converter, according to a comparative example. Referring to FIG. 1A, the converter 100A may include a power stage 102-A and a control circuit 104-A. The power stage 102-A may be configured to perform voltage conversion to transfer energy from voltage input Vᵢₙ to an output voltage Vₒᵤₜ. The control circuit 104-A may be configured to regulate the output voltage Vₒᵤₜ by adjusting the switching states of the transistors.

The power stage 102-A may include the input voltage Vᵢₙ, an inductor L, a transistor M (e.g., an n-channel metal-oxide semiconductor (NMOS) transistor), a diode D1, a capacitor C, a load with resistance R, and a pair of resistors (e.g., a first resistor R1 and a second resistor R2). The input voltage Vᵢₙ and the inductor L may be connected in series with the diode D1 at switching node Lₓ. Further, at the switching node Lₓ, the transistor M may be connected in parallel to the input voltage Vᵢₙ. The capacitor C, the load with resistance R, the pair of resistors R1 and R2, the transistor M, and the input voltage Vᵢₙ may be connected in parallel to each other. The source of the transistor M may be connected to the ground, and the drain of the transistor M may be connected to the switching node Lₓ. The input voltage Vᵢₙ may be supplied to the converter 100A, which may be adjusted by the power stage 102-A to provide the desired output voltage Vₒᵤₜ. The inductor L may store energy and may transfer the stored energy between input and output during the switching cycle. The transistor M may perform as the primary switching device that may control current flow through the inductor L. The diode D1 may provide a path for current when the switching transistor is off and may prevent a reverse current flow. The capacitor C may smoothen the output voltage Vₒᵤₜ and may reduce ripple, which may maintain relatively stable power delivery to the load. The load may receive power from the converter 100A. The pair of resistors R1 and R2 may form a part of a voltage divider used for feedback to the control circuit 104-A, which may allow the converter 100A to regulate the output voltage Vₒᵤₜ.

As shown in FIG. 1A, the control circuit 104-A may include a set-reset (SR) flip-flop, a buffer & driver, a comparator, a slope compensator, and an error amplifier. The error amplifier may compare a feedback signal V_{fb} from the output of the power stage 102-A with a reference voltage V_{ref}. The error amplifier may generate an error signal Vₑ. The slope compensator may stabilize the converter 100A, when operating at relatively high duty cycles, by adding a compensating signal Vₛₗₒₚₑ to potentially prevent instability. The sense signal Vₛₑₙₛₑ and the compensating signal Vₛₗₒₚₑ may be summed and the output Vₑ may be fed into the comparator as a first input. The error signal Vₑ output from the error amplifier may be fed into the comparator as a second input. The control circuit 104-A may process the error signal Vₑ and may generate control signals Ve that may adjust the duty cycle of the power stage 102-A. The output from the comparator may be fed to the SR flip-flop along with an oscillation clock. The SR flip-flop may manage the switching states of the transistor M, thereby ensuring a correct configuration of the switches for the buck and/or boost operation. The buffer & driver may provide a voltage and/or a current to the transistor M, to control the switch to turn on and/or turn off at the correct times.

FIG. 1B illustrates a circuit diagram 100B of a current sense amplifier (CSA) for performing dynamic switching, according to a comparative example. Referring to FIG. 1B, block 102-B may represent a first current mirror having a 1:n multiplication factor, where n is a positive integer greater than zero (0), which may include a pair of NMOS transistors (e.g., a fifth NMOS transistor MN5 and an eighth NMOS transistor MN8) and block 104-B may represent a second current mirror having an N:1 multiplication factor, where N is a positive integer greater than zero (0), which may include a pair of p-channel metal-oxide semiconductor (PMOS) transistors (e.g., a first PMOS transistor MP1 and a second PMOS transistor MP2). The CSA of circuit diagram 100B may have a current mirror multiplication factor of N. That is, the current in a mirrored branch of the current mirror may be N times the current in a primary branch of the current mirror.

Block 104-B (e.g., the first and second PMOS transistors MP1 and MP2) and block 106-B, which may include a first NMOS transistor MN1 and a second NMOS transistor MN2, may form a core structure of the current sense amplifier. The first NMOS transistor MN1, the second NMOS transistor MN2, the first PMOS transistor MP1, and the second PMOS transistor MP2 may be connected such that the current may be forced to be substantially similar and/or the same in block 104-B and block 106-B with the current mirror multiplication factor (or, a scaling factor) N.

As shown in FIG. 1B, I_{BIAS} may represent a relatively small bias current that may be used to set direct current (DC) operating conditions in the current sense amplifier. The I_{BIAS} current may be a constant current input to the block 102-B, which may be needed for creating current sinks and/or establishing a stable operating point for the core structure (e.g., blocks 104-B and 106-B) of the current sense amplifier.

LX1, which may be alternately referred to herein as a LX1 node, may represent a switching node where high-side and low-side switches meet, which may result in relatively rapid voltage transitions. The LX1 node may be connected to a power field effect transistor (FET) and may swing between the input voltage Vin and a ground voltage (e.g., 0 Volts (V) or GND1). The LX1 node may form one branch of the core structure of the current sense amplifier.

An SW_ON signal, which may be interchangeably referred to herein as a first input signal, may represent the control signal that may turn on and/or turn off the high-side switch. The SW_ON signal may be a switching signal with a duty cycle determined by a relationship between the input voltage Vᵢₙ and an output voltage Vₒᵤₜ.

The SEN_SW1 switch may be connected to a sense transistor and may carry a current that may be proportional to the current flowing from the high side switch.

In such a configuration, the high-side switch may supply current to a load through the LX1 node, while the SEN_SW1 node may monitor a portion of the supplied current via the sense transistor. The core structure of the current sense amplifier may operate in a positive feedback configuration, which may enable the current sense amplifier to respond to an instantaneous change in an inductor current. Due to the positive feedback, a zero-current state may be inherently stable for the core structure of the current sense amplifier.

The branch connected to the SEN SW1 switch may mirror the current 1/N times the current flowing through the LX1 branch, where N is the scaling factor.

As shown in FIG. 1B, V_{DD} may represent a power supply voltage for control and/or logic circuitry and, GND1 may represent a ground reference for the current sense amplifier.

Further, V_{SENS} may represent a final processed output from the current sense amplifier that may be forwarded to a slope compensation block for further processing.

Block 108-B may represent a current mirror including a pair of PMOS transistors (e.g., a fifth PMOS transistor MP5 and a sixth PMOS transistor MP6). The current mirror of the block 108-B may mirror current from a tenth NMOS transistor MN10 to an output branch of the current sense amplifier. In turn, the tenth NMOS transistor MN10 may mirror the current from the first NMOS transistor MN1 during the operation of the current sense amplifier, which may provide relatively accurate current scaling and may transfer current between the internal branches.

To transition the current sense amplifier relatively quickly out of the zero-current stable state, the eighth NMOS transistor MN8 of block 102-B may draw a current equal to n×I_{BIAS} from the LX1 node. In such a manner, the operating point of the core structure of the CSA may be established by forcing the core structure out of equilibrium.

The current flowing through the first NMOS transistor MN1, which may be proportional to the actual load current, may be mirrored to the tenth NMOS transistor MN10, thereby generating the V_{SENS} signal. When combined with slope compensation, the V_{SENS} signal may produce a V_{cs} signal. The V_{cs} signal may represent a processed voltage signal that may reflect a sensed current and may be used for regulating power delivery. The V_{cs} signal may be compared to a reference voltage by an error amplifier, which may amplify the difference (e.g., an error signal). Such an error signal may be used to generate control signals for a pulse width modulation (PWM) controller, which may adjust the duty cycle of power switches such as, but not limited to, the high-side and low-side FETs, to regulate the output voltage and/or output current.

As shown in FIG. 1B, the current sense amplifier may be dynamically switched on during each clock cycle when the current flows through the high side switch of the current sense amplifier. That is, in the current sense amplifier, the high-side switch may control power flow from an input to an inductor. When the high-side switch turns on, a current may begin to flow through the inductor, and the CSA may sense the current. This current sense information may be processed to generate a feedback signal to the PWM controller. The PWM controller may use the processed current sense information to adjust the duty cycle of the high side switch to maintain a desired output voltage while potentially avoiding overcurrent conditions. For example, the switch on-time for the CSA may be around 150 nanoseconds (ns), and the CSA may work within this period to provide real-time current measurements that may control the system of the circuit 100B to adjust the duty cycle.

Thus, it may be desired that the current sense amplifier may be sufficiently fast to respond at relatively high speeds (e.g., 150 ns or less) and track the current from the high-side switch.

The present disclosure may overcome the aforementioned drawbacks of the comparative example and may provide a relatively high-speed positive feedback current sense amplifier with a response time of less than 35 ns. However, embodiments of the present disclosure are not limited in this regard. The present disclosure provides a start-up circuit that may be added to the positive feedback current sense amplifier to bring the current sense amplifier to an active state relatively quickly. Thereby, potentially improving a large signal settling of the current sense amplifier circuit and/or enabling the current sense amplifier to track the high side switch current more accurately, when compared to a related current sense amplifier. The start-up circuit may generate a pulse as soon as the SEN_SW1 switch is switched on which in turn may activate a start-up switch of the start-up circuit to pull a certain amount of start-up current from the LX1 node, thereby moving the circuit to an active state relatively quickly, when compared to a related current sense amplifier.

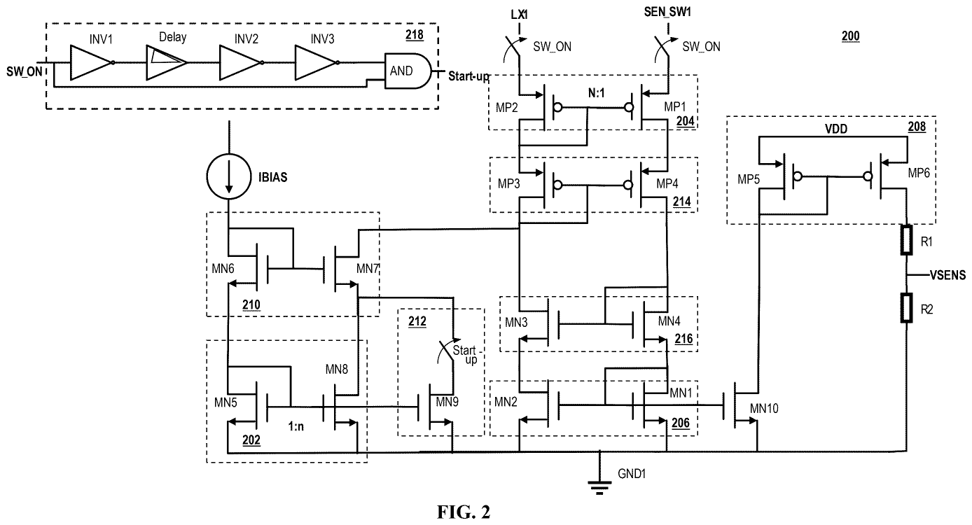

FIG. 2 illustrates a circuit diagram of a current sense amplifier 200, according to an embodiment of the present disclosure. Referring to FIG. 2, the current sense amplifier 200 may include a current sense amplifier core structure (e.g., a block 204 and a block 206), a start-up circuit 212, and a pulse generation circuit 218. The current sense amplifier 200 may further include a block 202 that may include a pair of power FETs (e.g., a fifth NMOS transistor NM5 and an eighth NMOS transistor MN8). The start-up circuit 212 may include a start-up switch connected to a ninth FET MN9. The ninth FET MN9 may be grounded and may be connected to the pairs of power FETs included in block 202 (e.g., the fifth and eighth NMOS transistors MN5 and MN9) and block 210 (e.g., a sixth NMOS transistor MN6 and a seventh NMOS transistor MN7) via the start-up switch 212. The pulse generation circuit 218 may be configured to switch on the start-up circuit 212 for a predefined time duration. The start-up circuit 212 may be configured to change the zero-current state of the current sense amplifier core structure to an active state. That is, the pulse generation circuit 218 may activate the start-up switch of the start-up circuit 212 for pulling current from the power FETs in the blocks 202 and 210 that may turn on the current sense amplifier core structure with a significantly improved response time (e.g., less than 35 ns), when compared to a related current sense amplifier, without significantly affecting a quiescent current and/or a quiescent area (e.g., a Q-point) of the current sense amplifier.

In an embodiment, the pulse generation circuit 218 may include a plurality of inverters (e.g., a first inverter INV1, a second inverter INV2, and a third inverter INV3) and at least one delay connected in series with each other, and an AND gate. The first input signal (e.g., SW_ON) may be provided to the pulse generation circuit 218. That is, the first input signal may be provided to the plurality of inverters INV1 to INV3 connected in series with the at least one delay. An output from the plurality of inverters INV1 to INV3 and the at least one delay may be forwarded to a first input the AND gate, and the second input of the AND gate may be directly connected to the first input signal in order to generate a pulse to switch on the start-up circuit 212. That is, the plurality of inverters INV1 to INV3 and the at least one delay of the pulse generation circuit 218 may generate a 180-degree phase shift signal that may be combined with first input signal in the AND gate to obtain the predefined time period. The predefined time period may be at least 40 ns, for example. However, embodiments of the present disclosure are not limited in this regard.

In an embodiment, the functionality of the I_{BIAS} current, the LX1 node, the SW_ON switch, the SEN_SW1 switch, the V_{DD} voltage, and the GND1 voltage may be similar in many respects to the corresponding elements described above with reference to FIG. 1B. Consequently, repeated descriptions of these elements described above with reference to FIG. 1B may be omitted for the sake of brevity. In an embodiment, the current sense amplifier core structure may include the first and second NMOS transistors MN1 and MN2 in block 206, and the first and second PMOS transistors MP1 and MP2 in block 204. To destabilize the zero current stable state of the current sense amplifier, the fifth and eighth NMOS transistors MN5 and MN8 may be added in block 202. For example, the eighth NMOS transistor MN8 may pull a current (e.g., 1 microampere (μA)) so that the currents in the two branches of the current sense amplifier core structure may not be the same. Further, an LX1 current and the sense current may be compared, and an equivalent signal may be mirrored to the tenth NMOS transistor MN10, which after going through the fifth and sixth PMOS transistors MP5 and MP6 in block 208, may generate the V_{SENS} voltage. In the current sense amplifier circuit 200, the ninth NMOS transistor MN9 and the start-up switch 212 may be added to pull a current for a predetermined time period (e.g., 40 ns) at the start of the SW_ON pulse. Thus, the current sense amplifier may start responding faster (e.g., within the predetermined time period), when compared to a related current sense amplifier. The pulse generation circuit 218 may generate a pulse having a time width of the predetermined time period (e.g., a 40 ns pulse) as soon as the SW_ON signal starts (becomes active).

In an embodiment, the third and fourth PMOS transistors MP3 and MP4 in block 214 may perform as protection devices for the first and second PMOS transistors MP1 and MP2 in block 204. Further, the third and fourth NMOS transistors MN3 and MN4 in block 216 may perform as protection devices for the first and second NMOS transistors MN1 and MN2 in block 206. The current sense amplifier core structure of the current sense amplifier 200 may be modified to work at a relatively high voltage according to design constraints and/or an input-output voltage configuration. As such the blocks 214, 216, and 210 may be added as protection for the input pairs of transistors in blocks 204, 206, and 202, respectively. For example, the current sense amplifier of the present disclosure may operate on a 22V supply and thus, protection devices may be needed. Alternatively or additionally, the output voltage may be relatively low (e.g., 5V), thereby, the minimum on time may be significantly reduced (e.g., to approximately 150 ns). However, embodiments of the present disclosure are not limited in this regard.

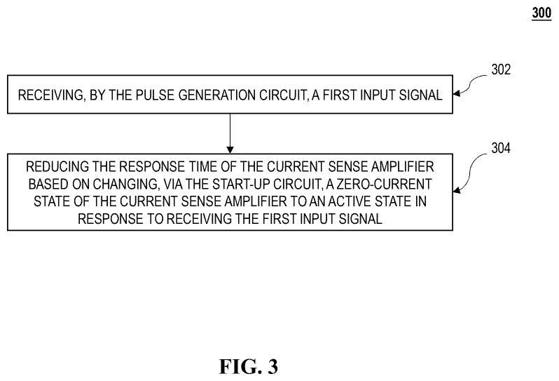

FIG. 3 illustrates a flowchart 300 of a method for reducing the response time of the current sense amplifier 200, according to an embodiment of the present disclosure. The current sense amplifier 200 may include the current sense amplifier core structure, the start-up circuit 212, and the pulse generation circuit 218.

At operation 302, the method may include receiving, by the pulse generation circuit 218, a first input signal SW_ON.

At operation 304, the method may include reducing the response time of the current sense amplifier 200 based on changing, via the start-up circuit 212, the zero-current state of the current sense amplifier to the active state in response to receiving the first input signal SW_ON. The current sense amplifier core structure may include a pair of power FETs. The start-up circuit 212 may include the start-up switch connected to a FET. The FET may be grounded and connected to the pair of power FETs via the start-up switch.

The method of the flowchart 300 may further include generating, by the pulse generation circuit, a pulse based on the first input signal, and providing the pulse to the start-up circuit, causing the start-up circuit to change the zero-current state of the current sense amplifier to the active state.

The generating of the pulse of the method of the flowchart 300 may include generating, by the pulse generation circuit, a 180-degree phase shift signal based on the first input signal, and generating the pulse by combining the 180-degree phase shift signal with the first input signal.

The generating of the pulse of the method of the flowchart 300 may include generating the pulse having a predefined time duration. The predefined time duration may have a time length of at least 40 ns.

The present disclosure provides the following technical advantages.

The start-up circuit of the present disclosure provides for bringing the buck-boost converter circuit relatively quickly to an active state from a zero current stable state, when compared to related buck-boost converter circuits.

The response time of the buck-boost converter circuit of the present disclosure may be significantly lower (e.g., 30 ns) than the response time of a related buck-boost converter circuit.

The various actions, acts, blocks, operations, or the like in the flow diagrams may be performed in the order presented, in a different order, or simultaneously. Further, in some example embodiments, some of the actions, acts, blocks, operations, or the like may be omitted, added, modified, skipped, or the like without departing from the scope of the present disclosure.

Unless otherwise defined, all technical and scientific terms used herein have the same meaning as commonly understood by one ordinary skilled in the art to which the present disclosure belongs. The system, methods, and examples embodiments provided herein are illustrative only and not intended to be limiting.

While specific language has been used to describe the present disclosure, any limitations arising on account thereto, are not intended. As would be apparent to a person of ordinary skill in the art, various working modifications may be made to the method to implement the present disclosure as taught herein. The drawings and the forgoing description give examples of some example embodiments. Those skilled in the art may appreciate that one or more of the described elements may well be combined into a single functional element. Alternatively or additionally, certain elements may be split into multiple functional elements. Elements from one example embodiment may be added to another example embodiment.

Some example embodiments disclosed herein may be implemented using at least one hardware device and performing network management functions to control the elements.

The foregoing description of some example embodiments may so fully reveal the general nature of some example embodiments herein that others may, by applying current knowledge, readily modify and/or adapt for various applications such specific example embodiments without departing from generic concepts, and, therefore, such adaptations and modifications should and are intended to be comprehended within the meaning and range of equivalents of the example embodiments disclosed herein. It is to be understood that the phraseology or terminology employed herein is for the purpose of description and not of limitation. Therefore, while some example embodiments herein have been described, those skilled in the art may recognize that some example embodiments herein may be practiced with modification within the scope of the present disclosure as described herein.

1. A current sense amplifier, comprising:
a current sense amplifier core structure comprising a pair of power field effect transistors (FETs);
a start-up circuit comprising a start-up switch coupled with a FET, wherein the FET is grounded and coupled with the pair of power FETs via the start-up switch; and
a pulse generation circuit configured to switch on the start-up circuit for a predefined time duration,
wherein the start-up circuit is configured to change a zero-current state of the current sense amplifier core structure to an active state.

2. The current sense amplifier of claim 1, wherein the pulse generation circuit comprises:
a plurality of inverters;
at least one delay; and
an AND gate,
wherein the plurality of inverters and the at least one delay are coupled in series with each other and to a first input of the AND gate.

3. The current sense amplifier of claim 2, wherein the pulse generation circuit is further configured to:
receive a first input signal of the start-up circuit,
provide the first input signal to the plurality of inverters and the at least one delay coupled in series with the first input of the AND gate, and to a second input of the AND gate, and
generate a pulse configured to switch on the start-up circuit, based on an output of the AND gate.

4. The current sense amplifier of claim 2, wherein the pulse generation circuit is further configured to:
generate, using the plurality of inverters and the at least one delay, a 180-degree phase shift signal,
combine, using the AND gate, the 180-degree phase shift signal with a first input signal, and
obtain the predefined time duration, based on an output of the AND gate.

5. The current sense amplifier of claim 1, wherein the predefined time duration has a time length of at least 40 nanoseconds (ns).

6. A method for reducing a response time of a current sense amplifier, the method comprising:
receiving, by a pulse generation circuit, a first input signal; and
reducing the response time of the current sense amplifier by changing, using a start-up circuit, a zero-current state of the current sense amplifier to an active state based on the receiving of the first input signal.

7. The method of claim 6, further comprising:
generating, by the pulse generation circuit, a pulse based on the first input signal; and
providing the pulse to the start-up circuit, causing the start-up circuit to change the zero-current state of the current sense amplifier to the active state.

8. The method of claim 7, wherein the generating of the pulse comprises:
generating, by the pulse generation circuit, a 180-degree phase shift signal based on the first input signal; and
generating the pulse by combining the 180-degree phase shift signal with the first input signal.

9. The method of claim 7, wherein the generating of the pulse comprises:
generating the pulse having a predefined time duration.

10. The method of claim 9, wherein the predefined time duration has a time length of at least 40 nanoseconds (ns).

11. A current sense amplifier, comprising:
a power stage comprising a first current mirror having a first multiplication factor;
a current sense amplifier core structure having a primary branch and a mirrored branch, and comprising:
a second current mirror having a second multiplication factor different from the first multiplication factor; and
a third current mirror having the second multiplication factor;
a start-up circuit coupled between the power stage and the current sense amplifier core structure;
a pulse generation circuit configured to activate the start-up circuit; and
an output stage comprising a fourth current mirror and configured to output a current sense voltage,
wherein a current in the mirrored branch is a multiple of a current in the primary branch.

12. The current sense amplifier of claim 11, wherein the pulse generation circuit comprises:
a plurality of inverters;
at least one delay; and
an AND gate, and
wherein the plurality of inverters and the at least one delay are coupled in series with each other and to a first input of the AND gate.

13. The current sense amplifier of claim 12, wherein the pulse generation circuit is further configured to:
receive a first input signal of the start-up circuit,
provide the first input signal to the plurality of inverters and the at least one delay coupled in series with the first input of the AND gate, and to a second input of the AND gate, and
generate a pulse configured to switch on the start-up circuit, based on an output of the AND gate.

14. The current sense amplifier of claim 12, wherein the pulse generation circuit is further configured to:
generate, using the plurality of inverters and the at least one delay, a 180-degree phase shift signal,
combine, using the AND gate, the 180-degree phase shift signal with a first input signal, and
obtain a predefined time duration, based on an output of the AND gate.

15. The current sense amplifier of claim 11, wherein the pulse generation circuit is further configured to:
switch on the start-up circuit for a predefined time duration,
wherein the predefined time duration has a time length of at least 40 nanoseconds (ns).

16. The current sense amplifier of claim 11, wherein the start-up circuit comprises:
a start-up switch configured to change a zero-current state of the current sense amplifier core structure to an active state; and
a field effect transistor (FET) coupled with the power stage via the start-up switch.

17. The current sense amplifier of claim 11, wherein the current sense amplifier core structure is configured to:
compare the current in the mirrored branch with the current in the primary branch; and
output, based on the comparison, an equivalent signal to the output stage.

18. The current sense amplifier of claim 11, wherein the power stage further comprises a first voltage protection block coupled with the first current mirror,
wherein the current sense amplifier core structure further comprises:
a second voltage protection block coupled with the second current mirror; and
a third voltage protection block coupled with the third current mirror.

19. The current sense amplifier of claim 11, wherein the first current mirror comprises a first pair of n-channel metal-oxide semiconductor (NMOS) transistors,
wherein the second current mirror comprises a first pair of p-channel metal-oxide semiconductor (PMOS) transistors,
wherein the third current mirror comprises a second pair of NMOS transistors, and
wherein the fourth current mirror comprises a second pair of PMOS transistors.

20. The current sense amplifier of claim 11, wherein the power stage is configured to:
set, based on a bias current, direct current (DC) operating conditions of the current sense amplifier.
